(19) United States
(12) Patent Application Publication
(10) Pub. No.: US 2013/0187275 A1
(43) Pub. Date: Jul. 25, 2013

(54) SEMICONDUCTOR DEVICE AND FABRICATION PROCESS THEREOF

(71) Applicant: Fujitsu Semiconductor Limited, Yokohama-shi (JP)

(72) Inventor: Hikaru Ohira, Yokohama (JP)

(73) Assignee: FUJITSU SEMICONDUCTOR LIMITED, Yokohama-shi (JP)

(21) Appl. No.: 13/728,132

(22) Filed: Dec. 27, 2012

(30) Foreign Application Priority Data
Jan. 25, 2012 (JP) 2012-013482

(51) Int. Cl. H01L 23/538; H01L 21/58

(52) U.S. Cl. CPC H01L 23/5384; H01L 21/58
USPC 257/758; 257/774; 257/762; 257/741; 438/107

(57) ABSTRACT

A three dimensional semiconductor integrated circuit device includes a stacking of a plurality of semiconductor chips each including a plurality of through via-plugs, in each of the semiconductor chips, a plurality of through via-plugs are connected commonly with each other by a connection pad provided on a top surface or bottom surface of the semiconductor chip, the connection pad on a top surface of a first semiconductor chip being joined directly to a corresponding connection pad on a bottom surface of a second semiconductor chip stacked thereon.

### CROSS-REFERENCE TO RELATED APPLICATIONS

The present application is based upon and claims the benefit of priority from the prior Japanese Patent Applications No. 2012-013482 filed on Jan. 25, 2012, the entire contents of which are incorporated herein by reference.

### FIELD

The embodiments described herein relate to semiconductor devices and manufacturing method thereof.

### BACKGROUND

With advancement of miniature processing technologies, it is now realized two-dimensional semiconductor integrated circuits of very large integration density. In a two-dimensional semiconductor integrated circuit device, a large number of semiconductor elements such as memories or logics are integrated on a silicon substrate with high density and a multilayer wiring structure is formed on such a silicon substrate for interconnecting these semiconductor elements.

With the prospect of increasing the integration density further, investigations are being made for three-dimensional semiconductor integrated circuit devices in which a large number of two-dimensional semiconductor integrated circuit devices are stacked.

### RELATED-ART DOCUMENTS

### Patent Document

Japanese Laid-Open Patent Application 2011-82450
Japanese Laid-Open Patent Application 2006

In such conventional three-dimensional semiconductor integrated circuit devices, it has been practiced in the art to form a large number of through via-plugs (TSV) in each of the semiconductor substrates carrying a two-dimensional semiconductor integrated circuit device and used for the stacking, wherein the two-dimensional semiconductor integrated circuit devices are stacked with each other and connected electrically and also mechanically to form the three-dimensional semiconductor integrated circuit device in such a manner that each of the through via-plugs in a silicon substrate carrying a two-dimensional semiconductor integrated circuit device is connected to a corresponding through via-plug of a silicon substrate located above and carrying another two-dimensional semiconductor integrated circuit device by way of soldering.

Because it is somewhat difficult to suppress lateral expansion of solder bumps in such a structure that connects the upper and lower through via-plugs by way of soldering, it has been practiced in the art to form and dispose the through via-plugs with an unnecessarily large diameter and unnecessarily large pitch for avoiding the problem of short circuit that may occur between neighboring solder bumps, although the through via-plugs themselves can be formed with much small diameter and can be disposed with a small pitch generally equal to twice the diameter of the through via-plugs.

Further, with such a conventional three-dimensional semiconductor integrated circuit device, in which a single via-plug is soldered upon another single via-plug and so on, there can be a case in which the entire line constituted by these via-plugs may become defective when there is caused a defect in any one of the via-plugs arrayed consecutively from the lowermost layer to the uppermost layer. Thus, such a three-dimensional semiconductor integrated circuit device suffers from the problem or poor yield and poor reliability. Further, with such a construction in which there exists a solder bump between a lower through via-plug and an upper via-plug, there arises a problem of increased wiring length, which in turn tends to invite the problems such as increase of parasitic impedance or increase of parasitic resistance.

### SUMMARY

In an aspect, there is provided a semiconductor device including: a first semiconductor chip having a first surface and a second surface opposite to the first surface, the first semiconductor chip including a first semiconductor element and a plurality of first through via-plugs each extending from the first surface to the second surface; and a second semiconductor chip having a third surface and a fourth surface opposite to the third surface, the third semiconductor chip including a second semiconductor element and a plurality of second through via-plugs each extending from the third surface to the fourth surface, the first semiconductor chip including a first connection pad on the first surface and a second connection pad on the second surface, two of the first through via-plugs neighboring with each other being connected commonly to the first connection pad at the first surface and the two first through via-plugs being connected commonly to the first connection pad at the second surface in the first semiconductor chip, the second semiconductor chip including a third connection pad on the third surface and a fourth connection pad on the fourth surface, one of the second through via-plugs being connected to the third connection pad at the third surface and the one second through via-plug being connected to the fourth connection pad at the fourth surface in the second semiconductor chip, the second semiconductor chip being stacked upon the first semiconductor chip such that the third surface faces the second surface, the second connection pad and the third connection pad being joined with each other.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a cross-sectional diagram representing the schematic construction of a three-dimensional semiconductor integrated circuit device according to a first embodiment;

FIG. 2 is a cross-sectional diagram representing a part of FIG. 1 surrounded with a broken line in detail;

FIG. 3 is a plan view diagram representing an example of array of through electrodes and connection pads on a semiconductor chip constituting the three-dimensional semiconductor integrated circuit device of FIG. 1;

FIG. 4 is a plan view representing an example of array of the through electrodes on a semiconductor chip according to a comparative example;

FIG. 5 is a plan view representing an example of array of the through electrodes on a semiconductor chip according to another comparative example;

FIG. 6 is a plan view diagram representing an example of an array of through electrodes and connection pads on a semiconductor chip according to a modification of the three-dimensional semiconductor integrated circuit device of FIG. 3;

FIGS. 7A-7P are diagrams explaining the fabrication process of a three-dimensional semiconductor integrated circuit device according to a first embodiment;

FIG. 8 is a cross-sectional diagram representing a part of a three-dimensional semiconductor integrated circuit device according to a modification;

FIG. 9 is a cross-sectional diagram representing a part of a three-dimensional semiconductor integrated circuit device according to a further modification of FIG. 8;

FIG. 10 is a cross-sectional diagram representing a part of a three-dimensional semiconductor integrated circuit device according to a further modification of FIG. 9.

### DESCRIPTION OF EMBODIMENTS

### First Embodiment

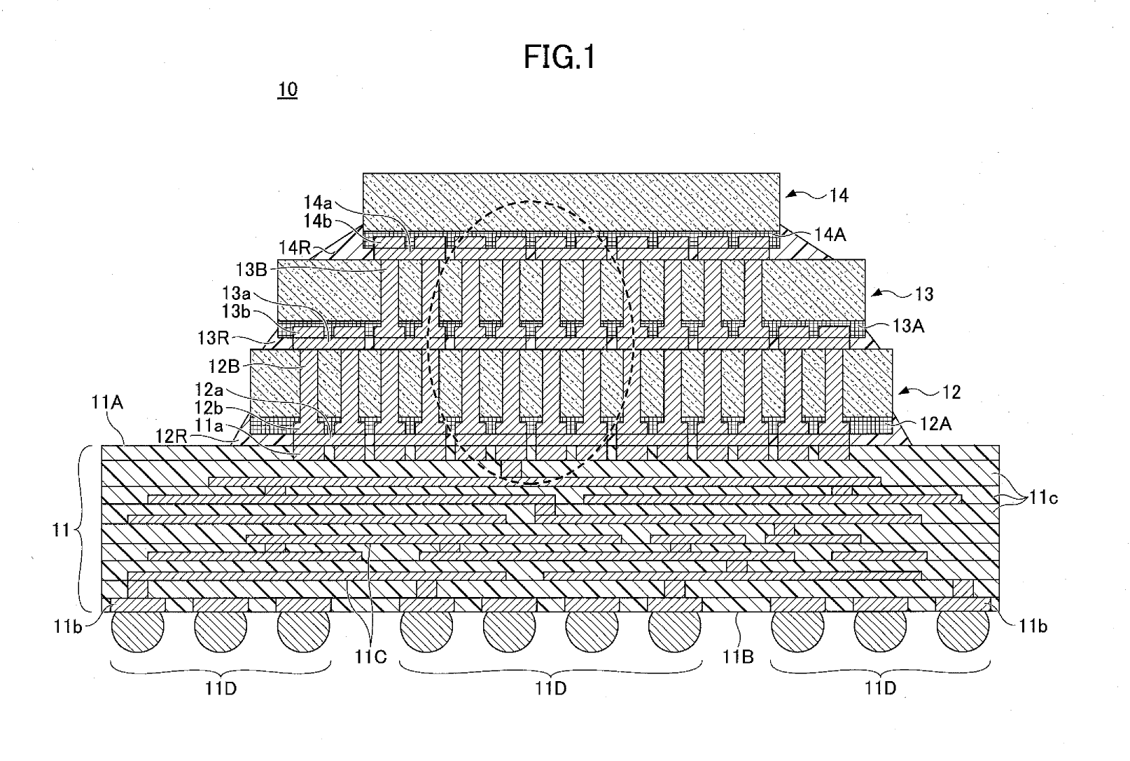

FIG. 1 is a cross-sectional diagram representing an example of a three-dimensional semiconductor integrated circuit device 10 according to a first embodiment.

Referring to FIG. 1, the three-dimensional semiconductor integrated circuit device includes a package substrate 11 having wiring pads 11a on a top principal surface 11A and wiring pads 11b on a bottom principal surface 11B, the package substrate 11 including therein alternate stacking of buildup insulator films 11c and wiring patterns 11C, a first semiconductor chip 12 flip-chip mounted upon the package substrate 11, a second semiconductor chip 13 flip-chip mounted upon the first semiconductor chip 12, and a third semiconductor chip 14 further flip-chip mounted upon the second semiconductor chip 13, wherein there are formed through via-plugs 12B of Cu, for example, in the semiconductor chip 12 in a row and column formation. Likewise, through via-plugs 13B of Cu are formed also in the semiconductor chip 13 in row and column formation.

The semiconductor chip 12 is formed with a semiconductor device such as a MOS transistor and a multilayer wiring structure 12A on a bottom principal surface thereof, wherein each of the through via-plugs 12B extends from the top principal surface to the bottom principal surface of the semiconductor chip 12 and is connected to the connection pad 12b of Cu, for example, formed in the multilayer wiring structure 12A at the bottom principal surface. The connection pads 12b are electrically connected to corresponding wiring pads 11a on the corresponding package substrate 11 via a connection pad 12a of Cu, for example. As a result, the semiconductor chip 12 is also connected to the package substrate 11 mechanically and firmly.

Likewise, the semiconductor chip 13 is formed with a semiconductor device such as a MOS transistor and a multilayer wiring structure 13A on a bottom principal surface thereof, wherein each of the through via-plugs 13B extends from the top principal surface to the bottom principal surface of the semiconductor chip 13 and is connected to a connection pad 13b of Cu, for example, forming a part of the multilayer wiring structure 13A at the foregoing bottom principal surface. Further, the connection pads 13b are connected electrically to corresponding through via-plugs 12B of the semiconductor chip 12 via a connection pad 13a of Cu, for example. As a result, the semiconductor chip 13 is also connected to the underlying semiconductor chip 12 mechanically and firmly.

Further, the semiconductor chip 14 is formed with a multilayer wiring structure 14A having electrode pads 14b at the bottom principal surface thereof, wherein the semiconductor chip 14 is connected electrically and mechanically to the semiconductor chip 13 by connecting the electrode pads 14b to corresponding through via-plugs 13B of the underlying semiconductor chip 13 via another connection pad 14a of Cu, for example.

The space between the package substrate 11 and the semiconductor chip 12 is sealed with a seal resin 12R, and the space between the semiconductor chip 12 and the semiconductor chip 13 is sealed likewise by a seal resin 13R. Further, the space between the semiconductor chip 13 and the semiconductor chip 14 is sealed with a seal resin 14R.

Further, there are formed solder bumps 11D on the bottom surface 11B of the package substrate respectively in correspondence to the electrode pads 11b.

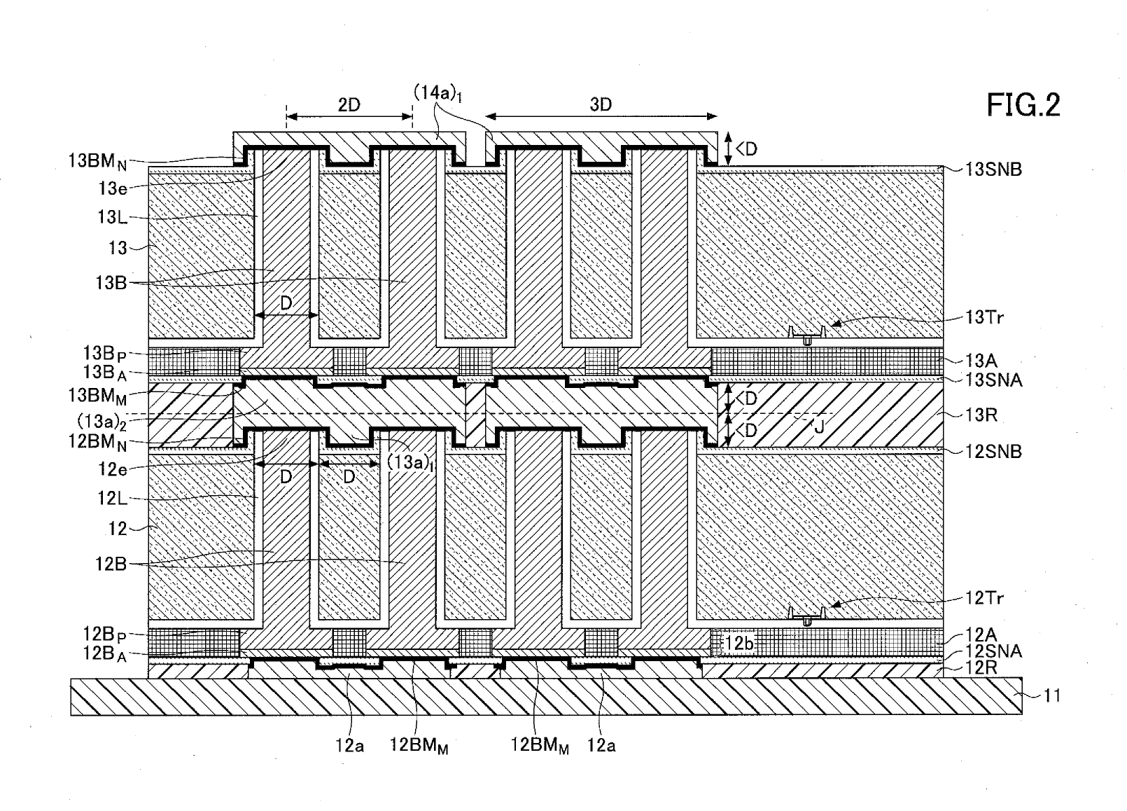

FIG. 2 is a cross-sectional diagram representing a part of the semiconductor integrated circuit device 10 of FIG. 1 surrounded with a broken line. Details of the package substrate 11 are not illustrated.

Referring to FIG. 2, the semiconductor chip 12 is formed with a MOS transistor 12Tr on the bottom principal surface on which the multilayer wiring structure 12A is formed. Likewise, the semiconductor chip 13 is formed with a MOS transistor 13Tr on the bottom principal surface on which the multilayer wiring structure 13A is formed.

The semiconductor chip 12 is formed with through via-plugs (TSV) 12B of Cu, for example, having a diameter D of 5 μm, for example, wherein the through via-plugs (TSV) 12B are formed in a row and column formation with an interval D equal to the diameter D, and hence with a pitch 2 D. Each of the through via-plugs 12B is formed in a through via-hole in the silicon chip 12 via a liner insulation film 12L of a thickness of 1 μm or less, for example, and further via a barrier metal film (not illustrated) of a thickness of 0.3 μm or less, for example. Likewise, the semiconductor chip 13 is formed with through via-plugs (TSV) 13B of Cu, for example, with a diameter D of 5 μm in a row and column formation, wherein the through via-plugs (TSV) 13B are formed with an interval D equal to the diameter D, and hence with a pitch 2 D. Each of the through via-plugs 13B is formed in a through via-hole in the silicon chip 13 via a liner insulation film 13L of a thickness of 1 μm or less, for example, and further via a barrier metal film (not illustrated) of a thickness of 0.3 μm or less, for example. For the liner films 12L and 13L, it is possible to use an oxide film formed by a CVD process that uses TEOS for the source, for example. For the barrier metal films (not illustrated), it is possible to form the barrier metal films by a refractory metal such as Ta or Ti by way of a PVD process.

Further, referring to FIG. 2, it will be noted that the through via-plugs 12B form, in the semiconductor chip 12, Cu connection pads 12Bp of a diameter larger than the diameter D of the through via-plug 12B on the bottom principal surface on which the multilayer wiring structure 12A is formed, and the connection pads 12B_{A} of Al, for example, are formed on such connection pads 12Bp. Further, it should be noted that the through via-plugs 12B projects the respective opposite ends upward from the top principal surface of the semiconductor chip 12 to form projecting ends 12e.

Further, the through via-plugs 13B form, in the semiconductor chip 13, Cu connection pads 13Bp of a diameter larger than the diameter D of the through via-plugs 13B on the bottom principal surface on which the multilayer wiring structure 13A is formed as a part of the multilayer wiring structure 13A, and the connection pads 13B_{A} of Al, for example, are formed on the respective connection pads 13Bp. Further, the through via-plugs 13B project the respective opposite ends upward from the top principal surface of the semiconductor chip 13 to form projecting ends 13e.

Further, there are formed passivation films 12SNA and 12SNB of SiN, or the like, on the bottom principal surface and top principal surface of the semiconductor chip 12, respectively. The passivation film 12SNA protects the multilayer wiring structure 12A while the passivation film 12B protects the periphery of the projecting ends 12e of the through via-plugs 12B.

Likewise, there are formed passivation films 13SNA and 13SNB of SiN, or the like, on the bottom principal surface and top principal surface of the semiconductor chip 13, respectively. The passivation film 13SNA protects the multilayer wiring structure 13A while the passivation film 13SNB protects the periphery of the projecting ends 13e of the through via-plugs 13B.

With the present embodiment, very fine through via-plugs 12B or 13B are formed in the semiconductor chip 12 or 13 with high density, and thus, it becomes possible to form a redundant structure that supplies a current or voltage by using a plurality of via-plugs 12B and 13B.

More specifically, on the top surface of the semiconductor chip 12, there are formed connection pads (13a)₁ of Cu for example, each formed with a height smaller than the diameter D of the via-plug (<D) to connect the projecting ends 12e of two neighboring through via-plugs 12B. Further, for the two via-plugs 13B of the semiconductor chip 13 corresponding to the foregoing two via plugs 12B, there are formed connection pads (13a)₂ of Cu for example, each formed with a height smaller than the diameter D of the via-plug (<D) to connect the respective via-plugs 13B with each other. Each connection pad (13a)₁ is joined to a corresponding connection pad (13a)₂ at a location represented by a broken line J by diffusion bonding to form a single connection pad 13a. Such a connection pad 13a has a size of three via-plugs (3 D) as represented in FIG. 2.

As will be explained layer, the bottom surface of the connection pad (13a)₁ is formed with a barrier metal film 12BM_{N} in the construction of FIG. 2, wherein a barrier metal film 12BM_{M} of a refractory metal such as Ta or Ti is formed on the top surface of the connection pad (13a)₂.

Likewise, there are connection pads (14a)₁ of Cu, for example, on the top surface of the semiconductor chip 13 wherein each connection pad (14a)₁ has a height smaller than the diameter D of the via-plug (<D) and connects the projecting end 13e of two neighboring through via-plugs 13B with each other. Further, while not illustrated, the connection pads (14a)₁ form the connection pads 14a of FIG. 1 by being diffusion bonded directly to similar connection pads each connecting two via-plugs 14B of the semiconductor chip 14 with each other.

In the construction of FIG. 2, a barrier metal film 13BM_{M} of a refractory metal such as Ta or Ti is formed on the bottom surface of the connection pad (14a)₁.

Further, the foregoing two via-plugs 12B are connected with each other by a connection pad 12a of Cu formed with a height smaller than the diameter D of the via-plugs (<D) at the respective connection pads 12B_{A}, wherein the connection pads 12a are joined to the corresponding wiring pads 11a of the package substrate 11 by way of diffusion bonding. A barrier metal film 12BM_{M} similar to those explained before is formed on the top surface of the connection pad 12a.

With such a construction, an electric current or voltage is supplied via two current paths corresponding to the two through via-plugs connected with each other, and thus, it is possible to avoid the failure of the three-dimensional semiconductor integrated circuit 10 even in the case there is caused a failure in one of these current paths. Thereby, the reliability and yield are improved.

Further, as represented in FIG. 2, the Cu pads (13a)₂ and (13a)₂, the Cu connection pads (14a)₂, and the Cu connection pads 12a are all formed with a height smaller than the diameter D of the through via-plugs 12B or 13B, and because of this, it becomes possible to reduce the overall height of the three-dimensional semiconductor integrated circuit device 10 of FIG. 1. Thereby, it becomes possible to reduce the size of the three-dimensional semiconductor integrated circuit device. As a result of such reduction in the height, the wiring length in the height direction is reduced, and in combination with the use of low resistance Cu connection pads 12a, 13a and 14a for the connection of the through via-plugs 12B and 13B in place of solder bumps, it becomes possible to suppress the degradation of operational speed of the three-dimensional semiconductor integrated circuit device 10 as a whole, which may otherwise be caused by the RC product. Thus, according to the present embodiment, it becomes possible to realize excellent operational speed in the three-dimensional semiconductor integrated circuit device 10.

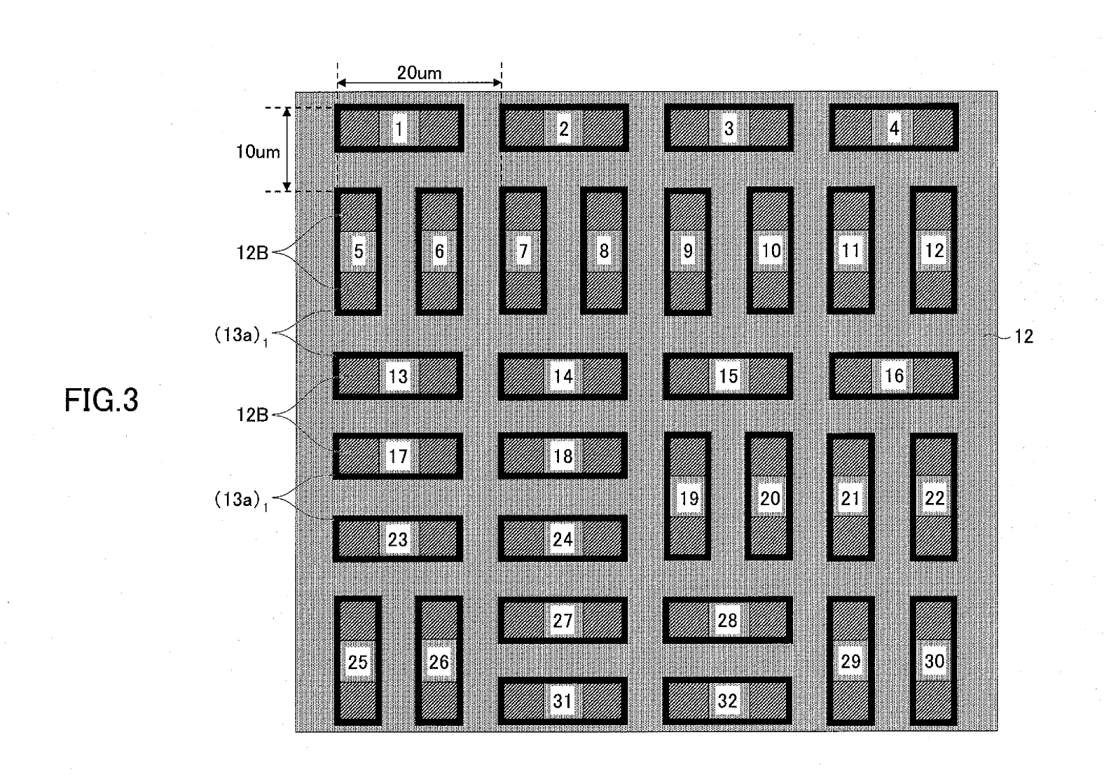

FIG. 3 is a plan view diagram looking down the semiconductor chip 12 of the three-dimensional semiconductor integrated circuit device 10 of FIG. 1 from above.

Referring to FIG. 3, the semiconductor chip 12 is formed with the via-plugs 12B of the diameter D of 5 μm, and thus formed with the via-plugs 12B having a square cross-sectional shape of an edge length of 5 μm, in a row and column formation with a pitch of 10 μm, which is twice as large as the diameter D. In the illustrated example, there are formed 64 via-plugs 12B (64=8×8) in all. By connecting each two via-plugs with each other by a connection pad (13a)₁, it becomes possible to realize 32 current paths while securing redundancy.

In the embodiment of FIG. 3, it should be noted that the direction of the array of the via-plugs 12B connected with each other by the connection pad (13a)₁ is arbitrary. In the illustrated example, the pairs aligned in the lateral direction in the drawing and the pairs aligned in the longitudinal direction in the drawing appear with the same number for avoiding mechanical vulnerability in a specific direction. However, it is not necessary that they appear in the same number. Meanwhile, it is also possible such that the pairs are aligned in a specific direction for facilitating the injection of sealing resin such as the sealing resin 13R.

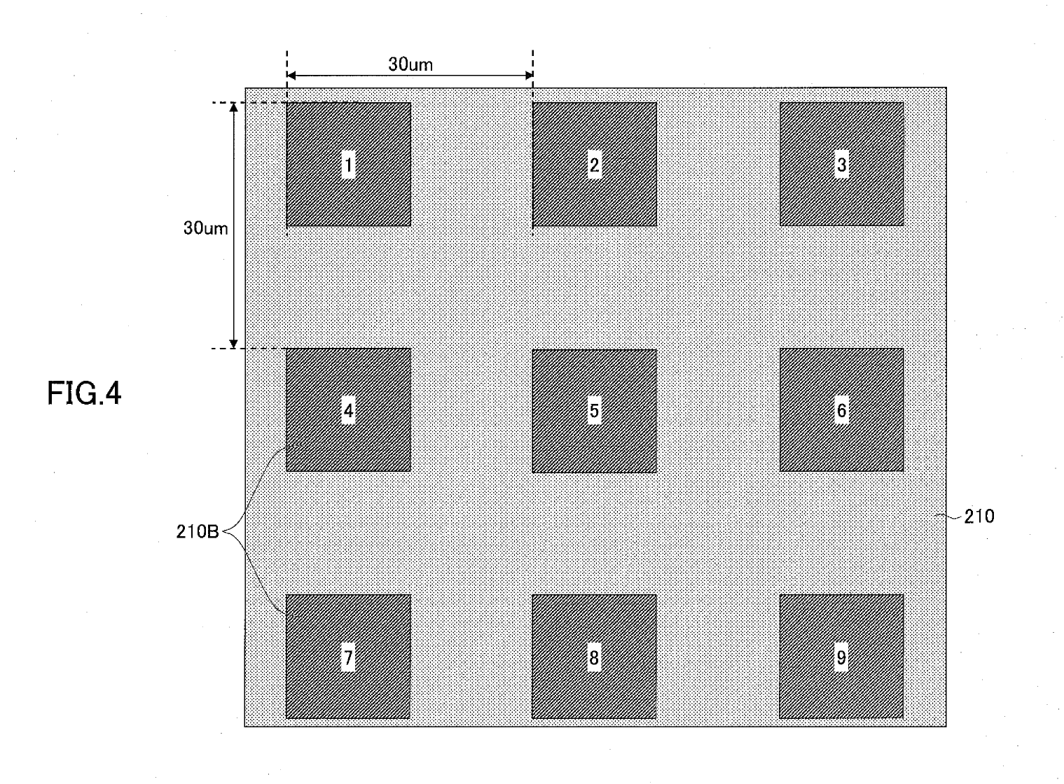

FIG. 4 is a plan view diagram representing the arrangement of the via-plugs according to a comparative example in which solder bumps are used for the connection of the via-plugs.

Referring to FIG. 4, the comparative example uses via-plugs 210B of a large square cross-section having an edge length of 15 μm for the soldering wherein the via-plugs 210B are formed in a row and column formation with a 30 μm pitch. In this case, however, only 9 current paths are secured but with no redundancy.

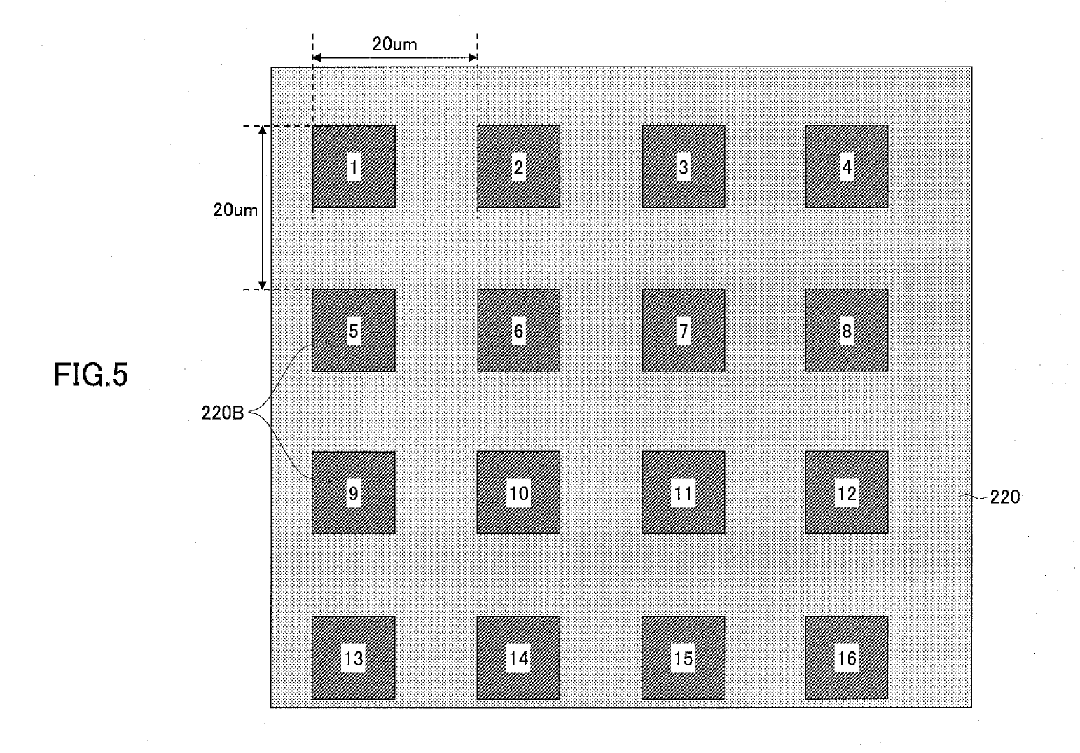

Further, FIG. 5 represents the case in which via-plugs 220B of a square cross-section having an edge length of 10 μm are disposed on a semiconductor chip 220 in a row and column formation with a 20 μm pitch. In this case, too, only 16 current paths are secured but without redundancy.

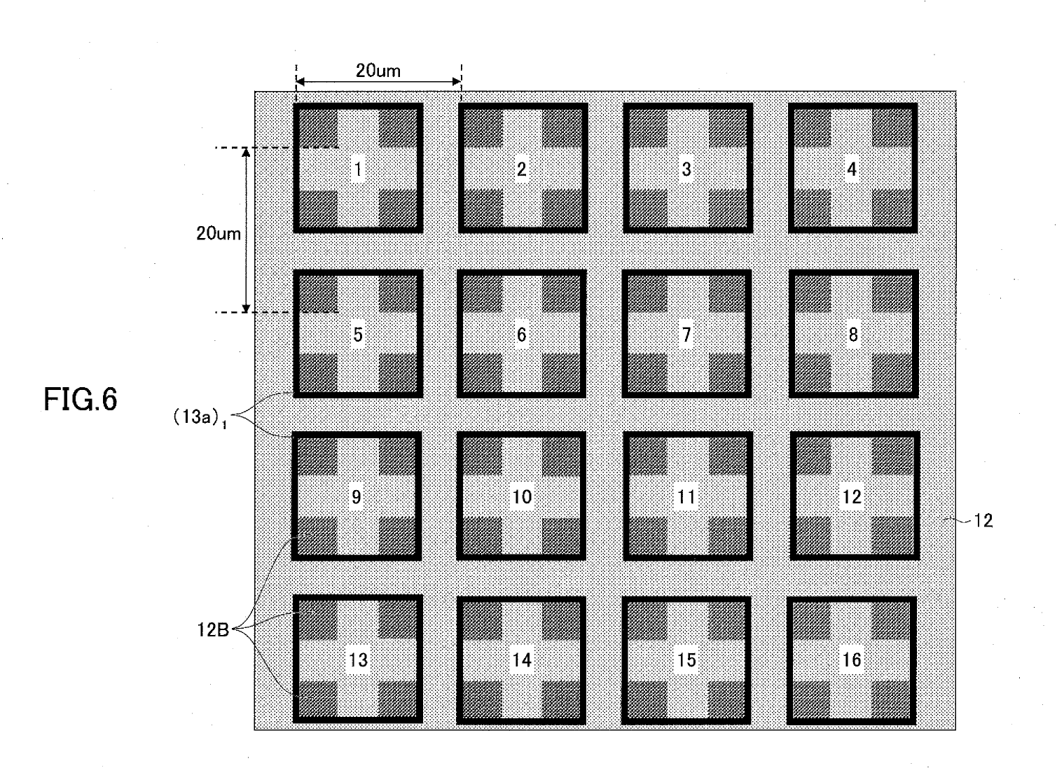

FIG. 6 is a plan view diagram representing a modification of the present embodiment in which each four via-plugs 12B, each having a size of 5 μm×5 μm and disposed together with other via-plugs to form a row and column formation with a pitch of 10 μm, are connected with each other to a single current path by a connection pad (13a)₁ of a square shape.

Referring to FIG. 6, it will be noted that such a construction further increases the degree of redundancy while still securing 16 current paths similarly to the case of FIG. 5.

It should be noted that for the sake of simplicity of explanation, the via-plugs of FIGS. 3-6 have been explained heretofore as having a square cross-sectional shape. However, the cross-sectional shape of the via-plugs is not limited to square and may have other shape such as a circular shape.

Thus, with the present embodiment, in which through via-plugs of small diameter are disposed in the semiconductor chips that constitute a three-dimensional semiconductor integrated circuit device with high density, it becomes possible to increase the degree of redundancy and also to increase the degree of freedom of constructing the current paths or signal paths in the three-dimensional semiconductor integrated circuit device, by rounding up a plurality of threading via-holes by way of using connection pads.

Further, by using the Cu connection pads for the connection of the through via-pugs in place of solder bumps, it becomes possible to reduce the height of the three-dimensional semiconductor integrated circuit device 10, and with this, it becomes possible to decrease the wiring length in the height direction. As a result, in addition to the improvement of yield or reliability caused by the increase of the degree of redundancy, there is attained decrease of signal delay, and it becomes possible to improve the electric characteristics such as improvement of operational speed with the three-dimensional semiconductor integrated circuit device 10.

Further, with the present embodiment, it is not necessary to align the individual through via-plugs 12B to corresponding through via-plugs 13B, as it is merely sufficient to align a connection pad such as the connection pad (13a)₁ to a corresponding connection pad such as the connection pad (13a)₂, and high precision is not needed for the alignment of the via-plugs. As a result, it becomes possible to improve the production throughput and yield of the semiconductor device.

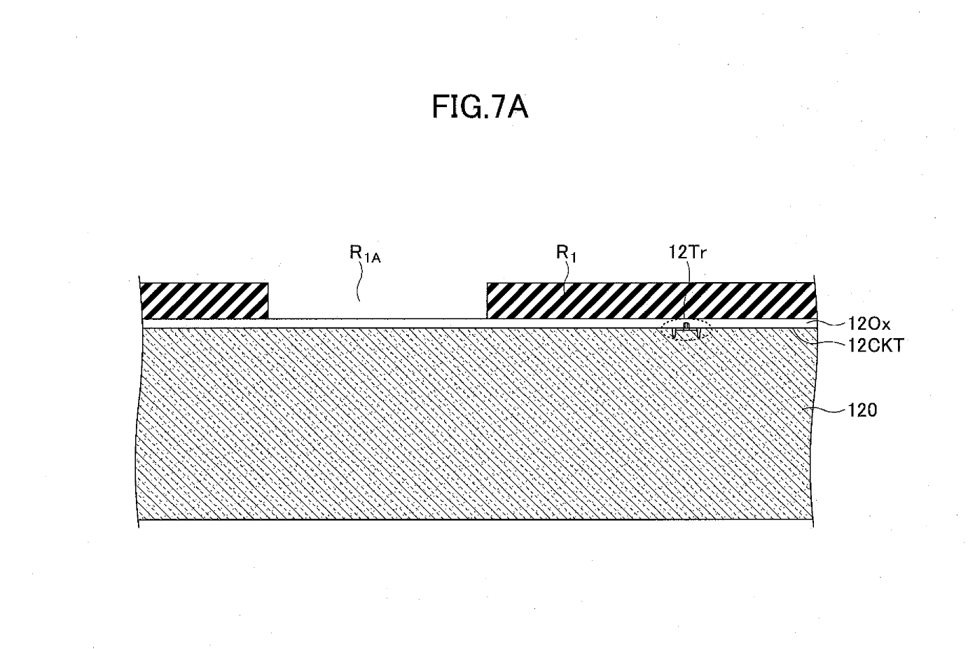

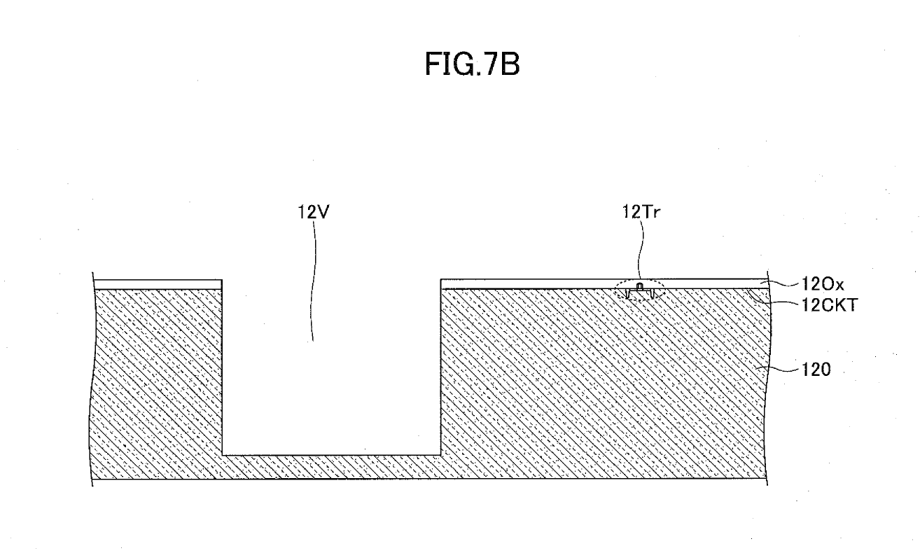

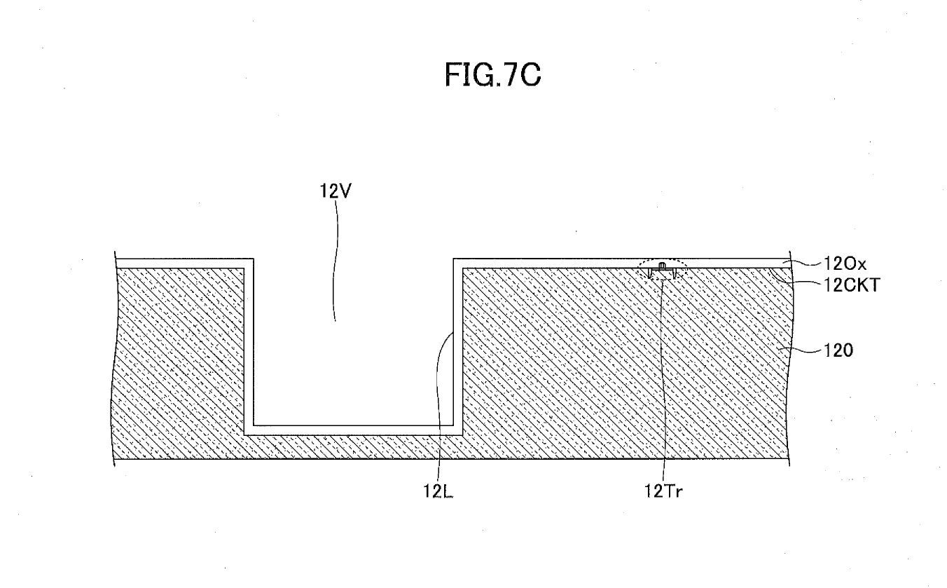

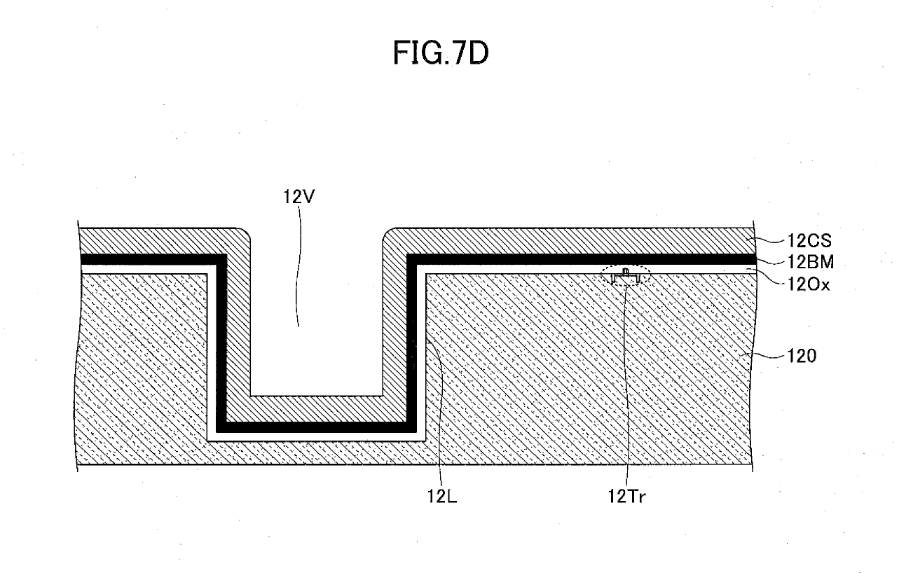

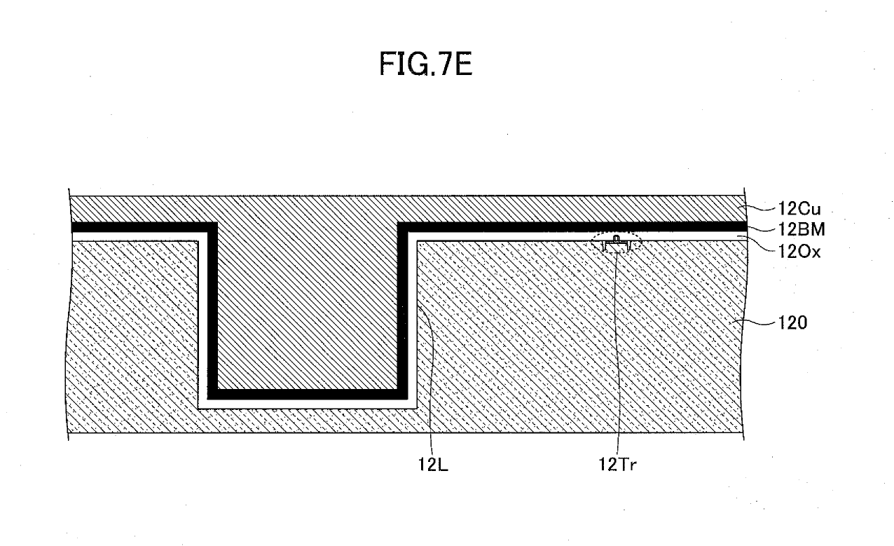

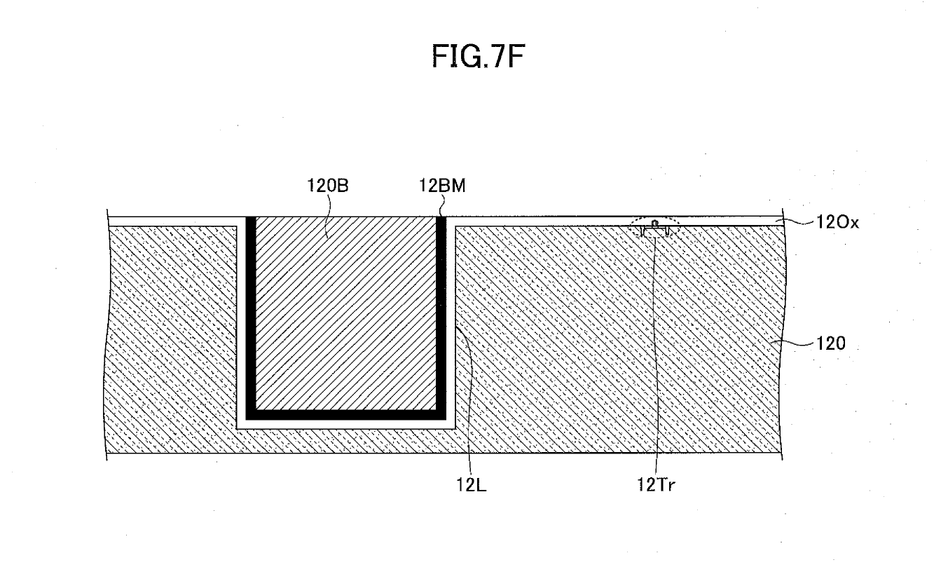

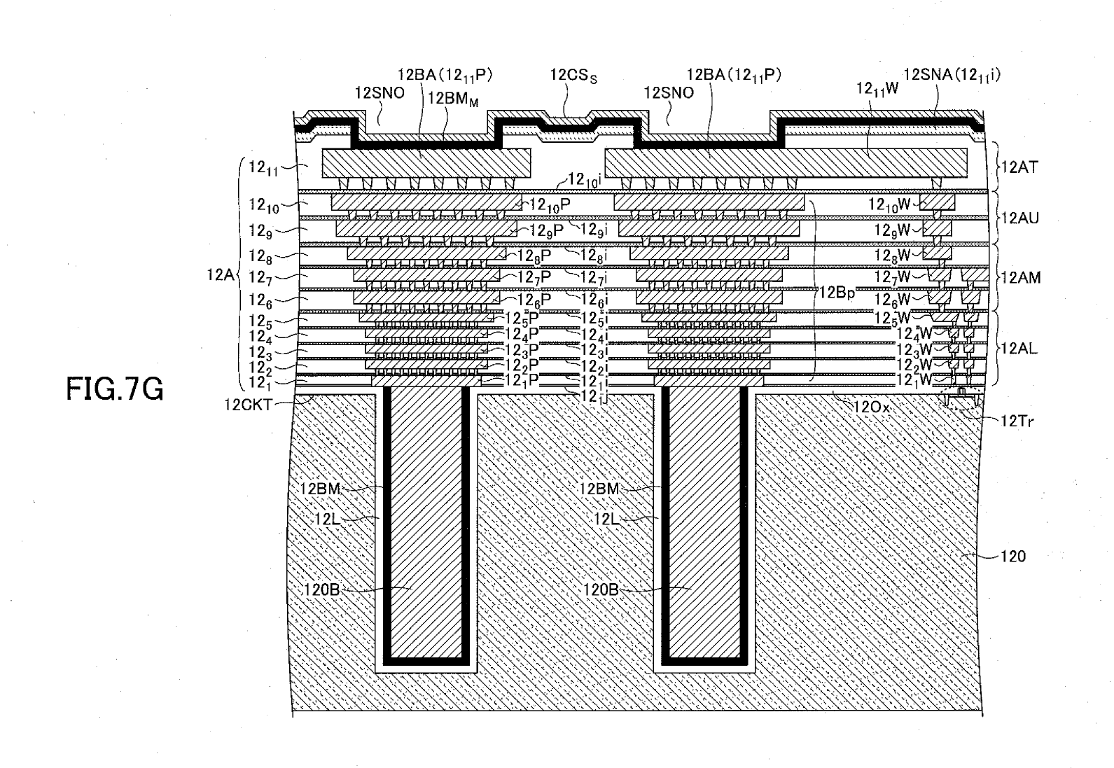

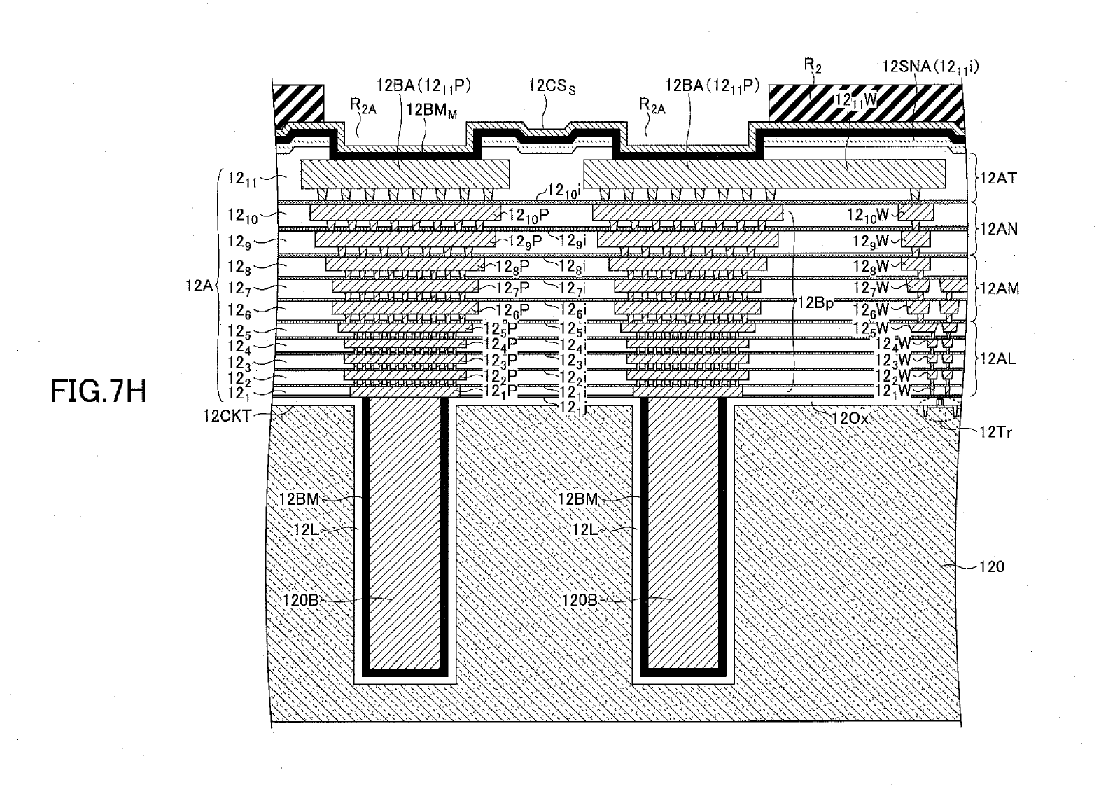

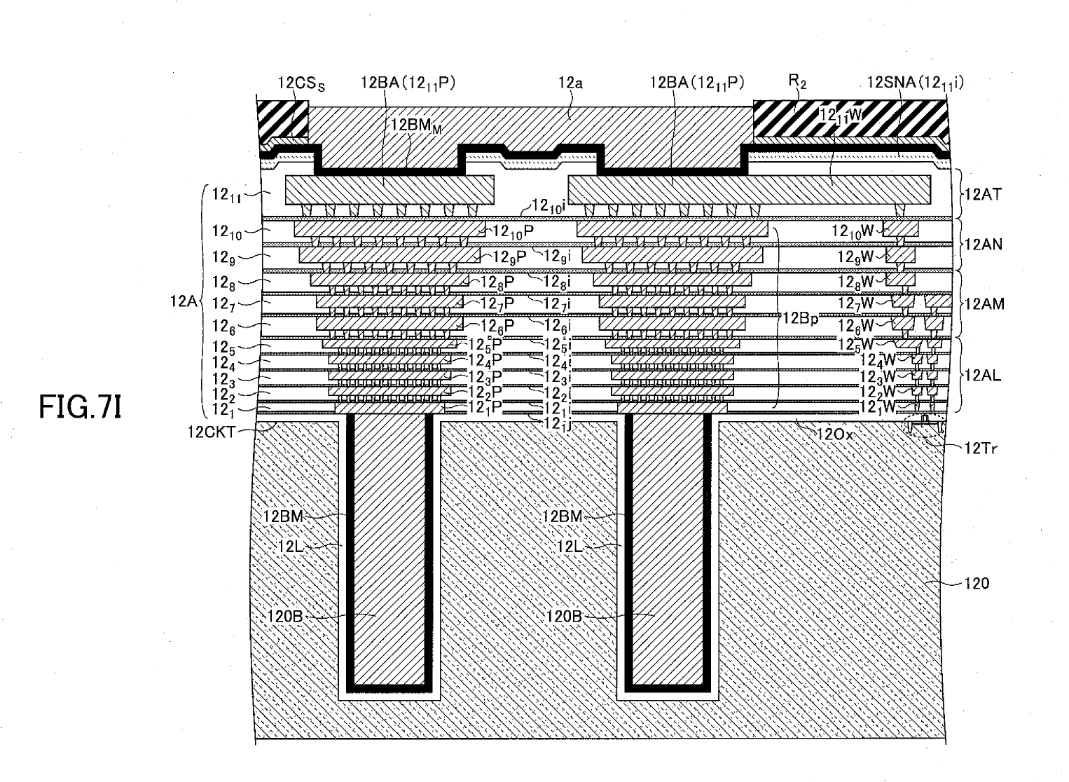

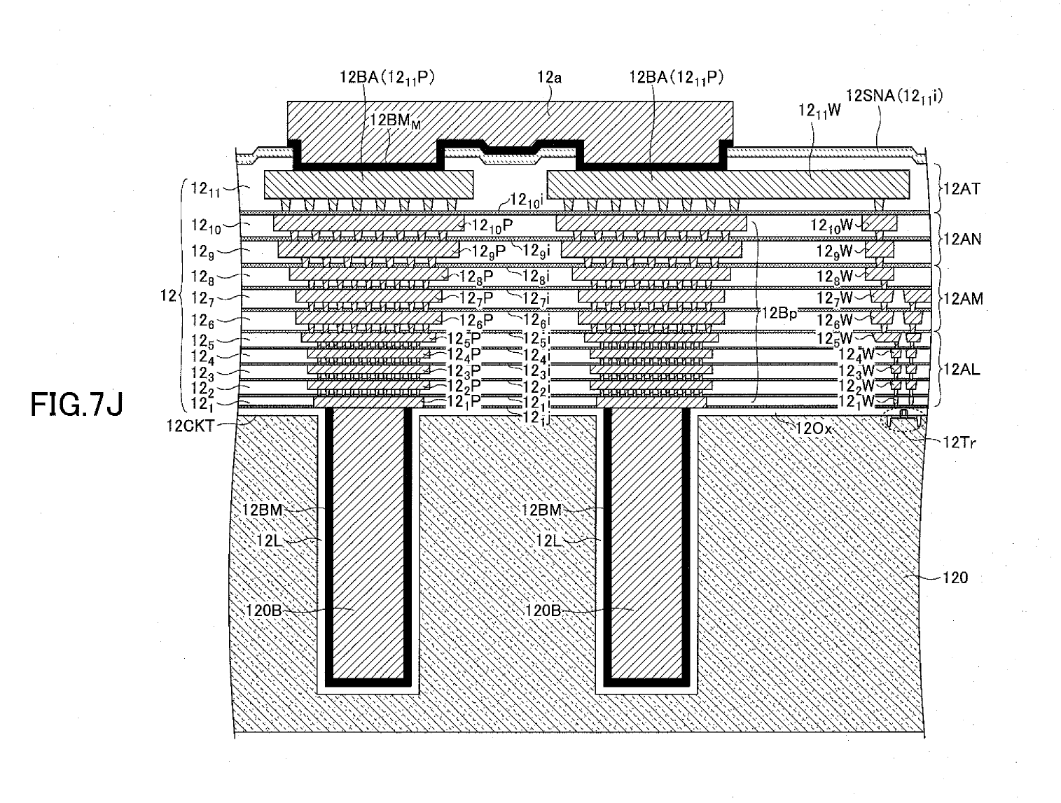

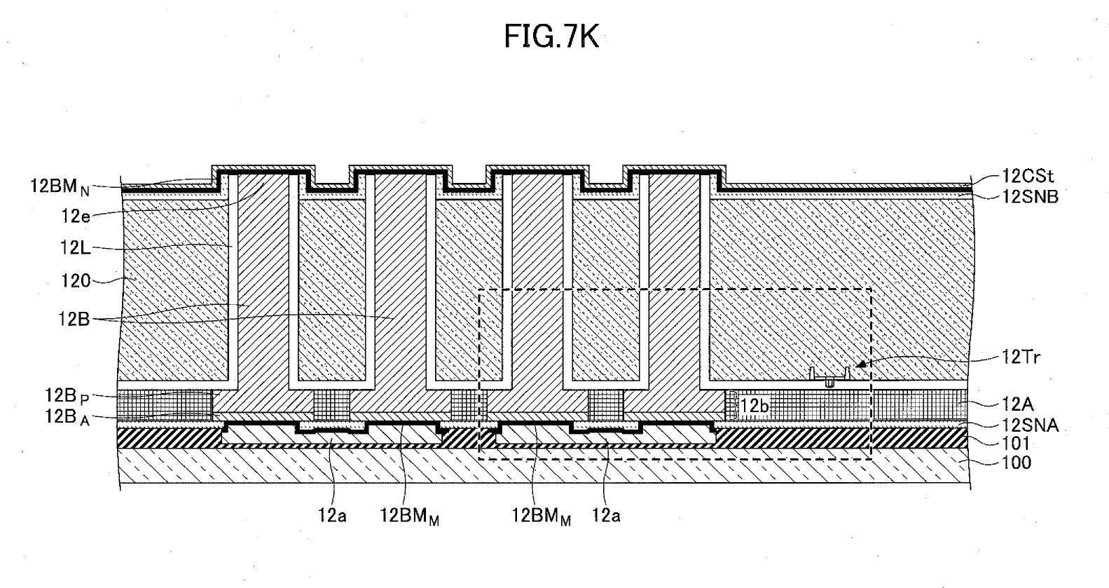

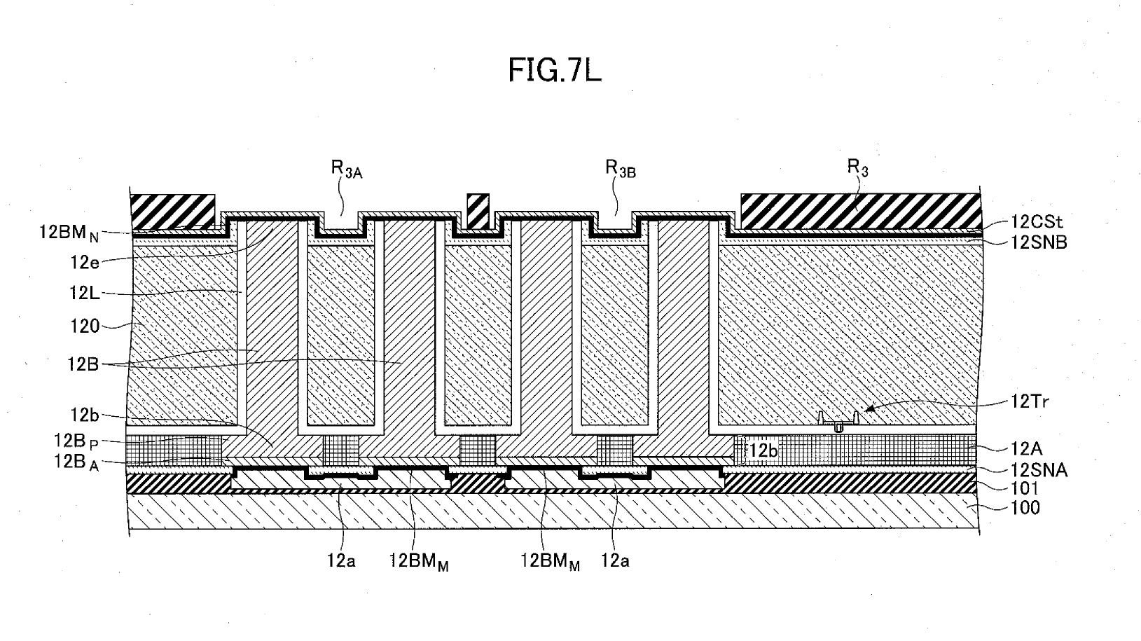

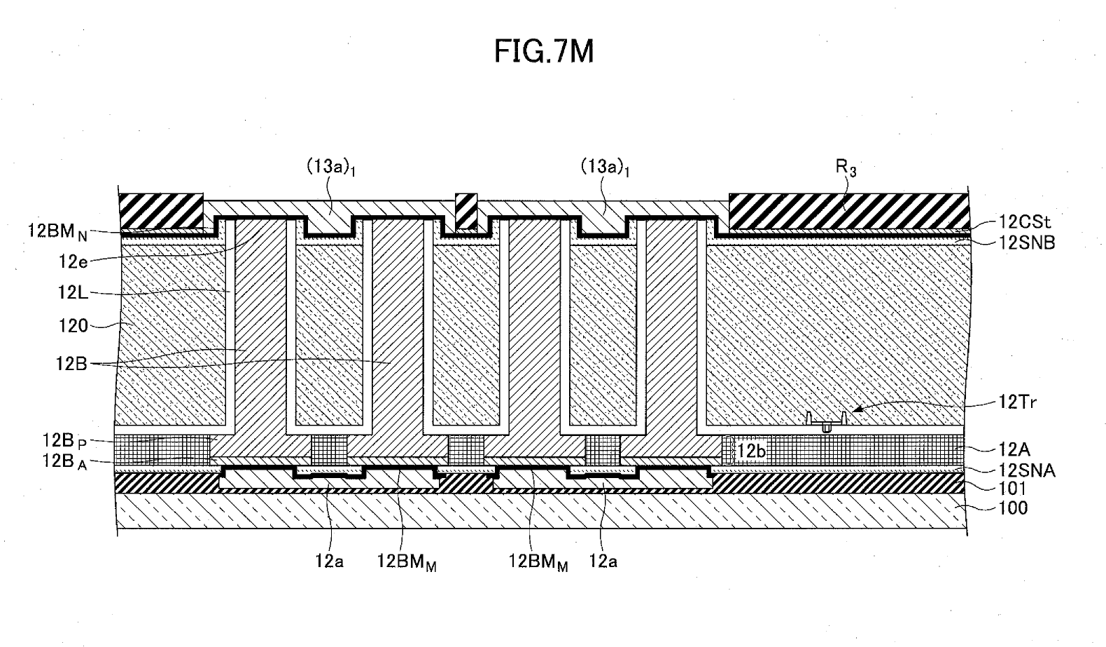

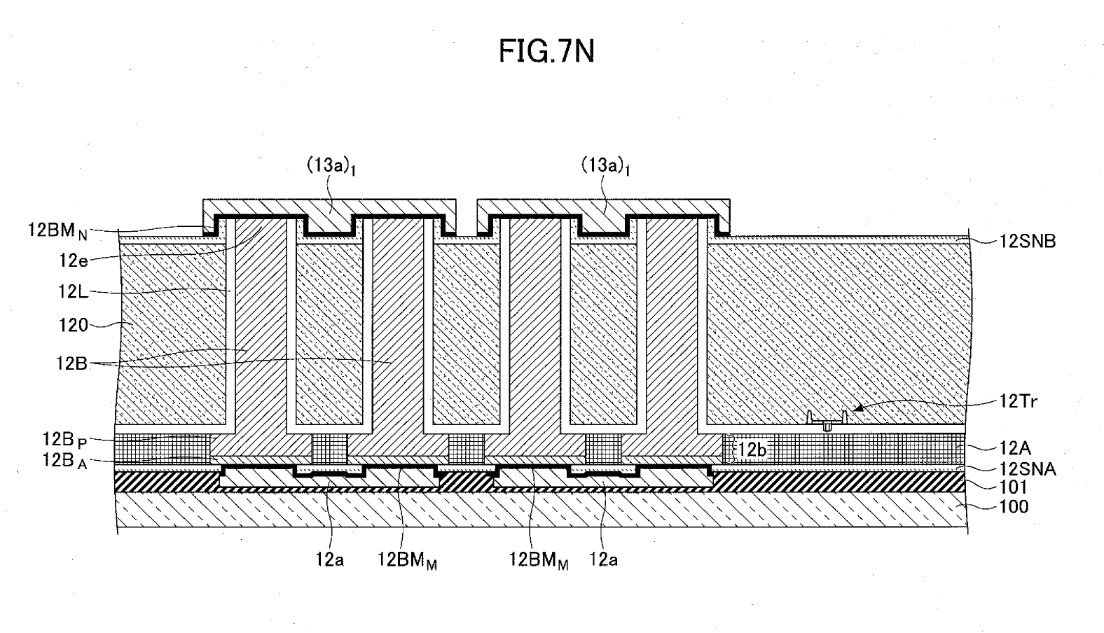

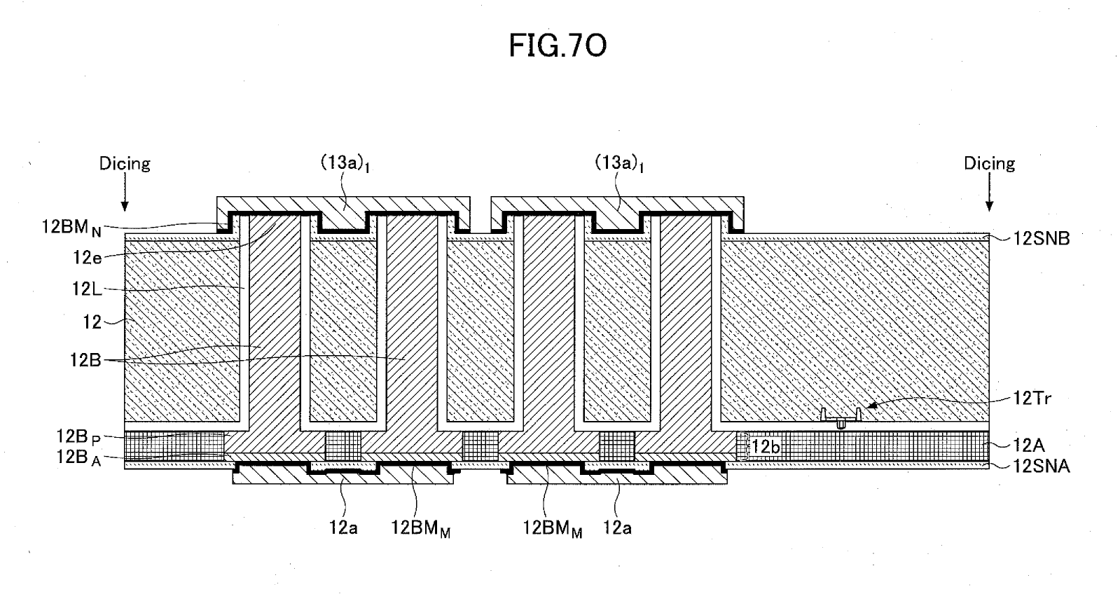

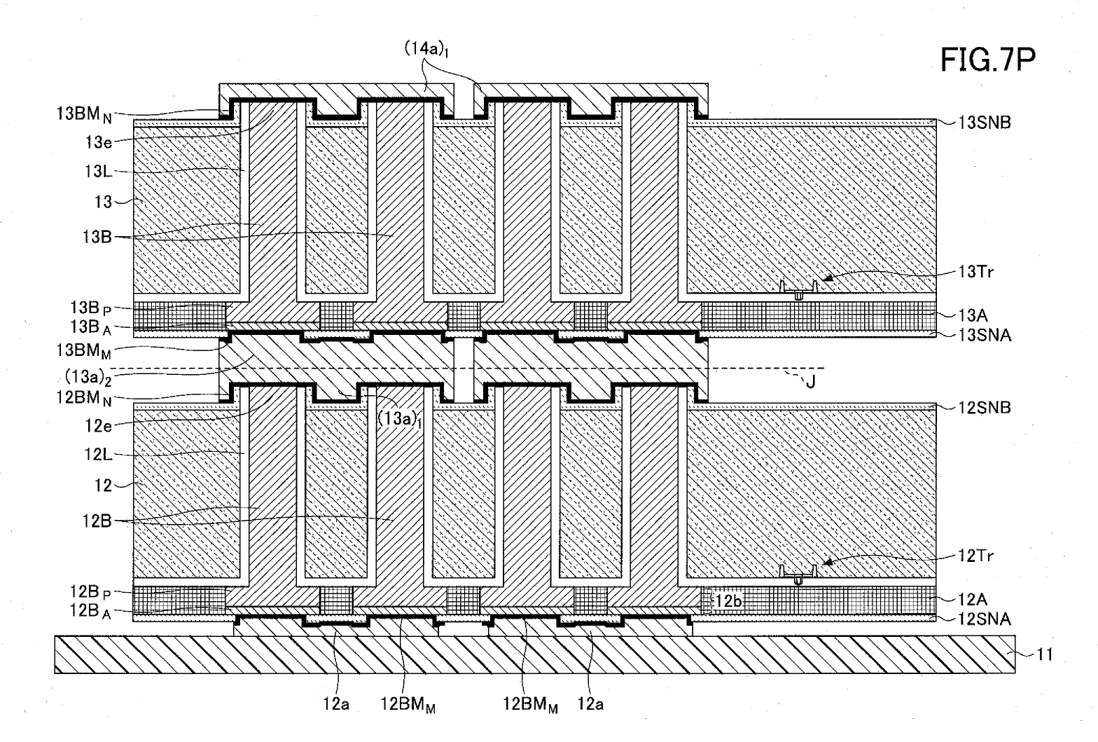

Next, the fabrication process of the three-dimensional semiconductor integrated circuit device 10 of the present embodiment will be explained with reference to FIGS. 7A-7P. Hereinafter, explanation will be made for the semiconductor chip 12. However, fabrication of the semiconductor chip 13 can be attained similarly.

Referring to FIG. 7A, a semiconductor element 12Tr, which may be a MOS transistor as noted before, is formed on a circuit formation surface 12CKT of a silicon wafer 120 constituting the semiconductor chip 12, the circuit formation surface 12CKT corresponding to the bottom principal surface of FIGS. 1 and 2, and there is formed a silicon oxide film 120x over the circuit formation surface 12CKT by a high-density plasma CVD process, or the like, to cover the semiconductor device 12Tr.

In the step of FIG. 7A, there is further formed a resist pattern R₁ on the silicon oxide film 120x wherein the resist pattern R₁ has resist openings R_{1A} respectively corresponding to the through via-plugs 12B explained previously. Further, in the step of FIG. 7B, the silicon wafer 120 is subjected to a deep reactive ion etching process while using the resist pattern R₁ as a mask, and with this, there are formed depressions 12V for the through via-plugs 12B repeatedly in correspondence to the resist openings R_{1A} with a diameter of 5 μm and a pitch of 10 μm, for example.

Further, in the step of FIG. 7C, a silicon oxide film is deposited on the silicon wafer 120 of the state of FIG. 7B by a high-density plasma CVD process, for example, in conformity with the shape of the depression 12V so as to cover the sidewall surface and the bottom surface thereof. With this, a liner film 12L is formed.

Further, in the step of FIG. 7D, a barrier metal film 12BM of a refractory metal such as Ta or Ti is formed on the structure of FIG. 7C by an MOCVD process or sputtering process, for example, and a Cu seed layer 12CS is formed thereon by an non-electrolytic plating process or sputtering process, for example.

Further, in the step of FIG. 7E, the structure of FIG. 7D is dipped into an electroplating bath and there is formed a Cu layer 12Cu to fill the depression 12V by feeding electric current to the Cu seed layer 12CS.

Further, in the step of FIG. 7F, unnecessary Cu layer 12Cu and barrier metal film 12BM on the silicon wafer 120 are removed by polishing conducted by a chemical mechanical polishing process (CMP), until the silicon oxide film 120x is exposed. As a result, the silicon wafer 120 is formed with Cu via-plugs 120B in correspondence to the through via-plugs 12B in a row and column formation with a diameter of 5 μm and a pitch of 10 μm in a state in which the sidewall surface and the bottom surface are covered with the barrier metal film 12BM and the liner oxide film 12L. In the state of FIG. 7F, the Cu via-plugs 12B are not yet formed to penetrate through the silicon wafer 120.

Further, in the step of FIG. 7G, the multilayer wiring structure 12A is formed on the circuit formation surface 12CKT of the silicon wafer 120.

In the example of FIG. 7G, the multilayer wiring structure 12A is formed of a lower layer part 12AL, a middle layer part 12AM, an upper layer part 12AU and an uppermost layer part 12AT. The lower layer part 12AL is formed of so-called Low-K film and includes a stacking of interlayer insulation films 12₁-12₅ having a first film thickness, wherein the interlayer insulation films 12₁-12₅ are formed respectively with Cu wiring patterns 12₁W-12₅W and corresponding Cu via-plugs by a dual damascene process. The Cu wiring patterns 12₁W-12₅W are connected to an active region of the semiconductor device 12Tr such as a source region, a drain region or a gate electrode via a W (tungsten) contact plug (not illustrated). Further, in correspondence to the Cu via-plug 120B, there are formed connection pads 12₁P-12₅P of Cu respectively in the interlayer insulation films 12₁-12₅ simultaneously with the Cu wiring patterns 12₁W-12₅W by a dual damascene process, wherein it will be noted that the connection pad 12₁P is formed in contact with the Cu via-plug 120B while the connection pads 12₂P-12₅P are connected to respective underlying connection pads immediately below by way of a large number of via-plugs. Thus, the connection pads 12₂P-12₅P are respectively supported on an underlying connection pad mechanically by way of the large number of Cu via-plugs. The connection pads 12₁P-12₅P constitute a part of the Cu wiring patterns 12₁W-12₅W, respectively.

Further, the middle layer part 12AM includes a stacking of interlayer insulation films 12₆-12₈ formed of a silicon oxide film, for example, and having a second film thickness thicker than the first film thickness, wherein the interlayer insulation films 12₆-12₈ are respectively formed with Cu wiring patterns 12₆W-12₈W and corresponding Cu via-plugs by way of a dual damascene process, with a width broader than the Cu wiring patterns 12₁W-12₅W and the via-plugs corresponding thereto. The Cu wiring patterns 12₆W-12₈W are connected to the active region of the semiconductor device 12Tr such as the source region, the drain region or the gate electrode via the Cu wiring patterns 12₁W-12₅W and the corresponding Cu via-plugs of the lower layer part 12AL. Further, in correspondence to the Cu via-plug 120B, there are formed connection pads 12₆P-12₈P of Cu respectively in the interlayer insulation films 12₆-12₈ by a dual damascene process simultaneously with the Cu wiring patterns 12₆W-12₈W, wherein it will be noted that each of the connection pads 12₆P-12₈P is connected to an underlying connection pad immediately below by way of a large number of via-plugs. Thus, the connection pads 12₆P-12₈P are supported mechanically by respective underlying connection pads immediately below by way of the large number of Cu via-plugs. The connection pads 12₆P-12₈P constitute a part of the Cu wiring patterns 12₁W-12₅W, respectively

Further, the upper layer part 12AU includes a stacking of interlayer insulation films 12₉-12₁₀ formed of a silicon oxide film, for example, and having a third film thickness thicker than the second film thickness, wherein the interlayer insulation films 12₉-12₁₀ are respectively formed with Cu wiring patterns 12₉W-12₁₀W and corresponding Cu via-plugs by way of a dual damascene process, with a width broader than the Cu wiring patterns 12₆W-12₈W and the via-plugs corresponding thereto. The Cu wiring patterns 12₉W-12₁₀W are connected to the active region of the semiconductor device 12Tr such as the source region, the drain region or the gate electrode via the Cu wiring patterns 12₆W-12₈W and the corresponding Cu via-plugs of the middle layer part 12AM and further via the Cu wiring patterns 12₁W-12₅W and the corresponding Cu via-plugs of the lower layer part 12AL. Further, in correspondence to the Cu via-plug 120B, there are formed connection pads 12₉P-12₁₀P of Cu respectively in the interlayer insulation films 12₉-12₁₉ by a dual damascene process simultaneously with the Cu wiring patterns 12₉W-12₁₀W, wherein it will be noted that the connection pads 12₉P-12₁₀P are connected to respective underlying connection pads immediately below by way of a large number of via-plugs. Thus, the connection pads 12₉P-12₁₀P are supported mechanically by respective underlying connection pads immediately below by way of the large number of Cu via-plugs. The connection pads 12₉P-12₁₀P constitute a part of the Cu wiring patterns 12₉W-12₁₀W, respectively

Here, the Cu connection pads 12₁P-12₁₀P constitute the connection pad 12Bp in the construction of FIG. 2.

Further, the uppermost layer part 12AT includes an interlayer insulation film 12₁₁ formed of a silicon oxide film, for example, and having a fourth film thickness thicker than the third film thickness, wherein the interlayer insulation film 12₁₁ is formed with an Al wiring pattern 12₁₁W and corresponding W via-plugs with a width broader than the Cu wiring patterns 12₉W-12₁₀W and the via-plugs corresponding thereto. The Al wiring pattern 12₁₁W is connected to the active region of the semiconductor device 12Tr such as the source region, the drain region or the gate electrode via the Cu wiring patterns 12₉W-12₁₀W and the corresponding Cu via-plugs of the upper layer part 12AU, via the Cu wiring patterns 12₆W-12₈W and the corresponding Cu via-plugs of the middle layer part 12AM, and further via the Cu wiring patterns 12₁W-12₅W and the corresponding Cu via-plugs of the lower layer part 12AL. Further, in correspondence to the Cu via-plug 120B, there is formed a connection pad 12₁₁P of Al in the interlayer insulation film 12₁₁ simultaneously with the Al wiring pattern 12₁₁W, wherein it will be noted that the connection pad 12₁₁P is connected to the underlying connection pad immediately below by way of a large number of W via-plugs. Thus, the connection pad 12₁₁P is supported mechanically by the underlying connection pad immediately below by way of the large number of W via-plugs. The connection pad 12₁₁P constitutes a part of the Al wiring pattern 12₁₁W. Here, the Al connection pad 12₁₁P constitutes the connection pad 12B_{A} in the construction of FIG. 2.

Further, with the construction of FIG. 7G, there is formed an insulating barrier film 12₁i of SiC or SiN between the interlayer insulation film 12₁ and the silicon oxide film 120x, while the interlayer insulation films 12₁-12₁₁ carry similar insulating barrier films 12₁i-12₁₁i respectively on the top surfaces thereof. Here, the insulating barrier film 12₁₁i constitutes the passivation film 12SNA of the construction of FIG. 2.

Further, with the step of FIG. 7G, there is formed an opening 12SNO in the passivation film 12SNA to expose the Al connection pad 12BA, and a barrier metal film 12BM_{M} of a refractory metal such as Ta or Ti and a Cu seed layer 12CS_{S} are formed further on the passivation film 12SNA to cover Al connection pad 12BA in the opening 12SNO.

Further, in the step of FIG. 7H, there is formed a resist pattern R₂ having a resist opening R2A on the Cu seed layer 12CS_{S} such that two neighboring Cu via-plugs 120B are included in the resist opening R2A, and an electrolytic plating process of Cu is conducted in the step of FIG. 7I to fill the resist opening R2A with a Cu layer. With this, the connection pad 12a is formed.

Further, in the step of FIG. 7J, the resist pattern R2 is removed and the Cu seed layer 12CSS and the barrier metal film 12bMM remaining on the passivation film 12SNA are removed further by a sputter etching process, or the like. Further in the step of FIG. 7K, the structure thus obtained is bonded upon the a support substrate 100 by a temporary adhesive layer 101 such that the side formed with the multilayer wiring structure 12A and the connection pad 12a makes a contact with the support substrate 100. It should be noted that FIG. 7K represents an area wider than the area of FIG. 7J, and thus, the part of FIG. 7K surrounded by a broken line corresponds to the part represented in FIG. 7J.

Further, in the step of FIG. 7K, the silicon wafer 120 is subjected to a grinding process at a principal surface opposite to the side of the circuit formation surface 12CKT. Further by applying a dry etching process or wet etching process, a structure is obtained such that the other end 12e of the Cu via-plug 120B is projected from the opposite principal surface as represented in FIG. 7K in the state covered with the liner insulation film 12L. With this, the Cu via-plug 120B now forms a through via-plug 12B.

Further, in the step of FIG. 7K, the passivation film 12SNB is deposited on the exposed principal surface of the silicon wafer 120 in conformity with the shape of the end 12e of the Cu via-plug 120B such that the passivation film 12SNB covers both the sidewall surface and the top surface of the exposed end 12e, and a resist film (not illustrated) is coated to cover the end 12e of the Cu via-plug 120B including the passivation film 12SNB. Next, a dry etchback process is applied while using the resist film (not illustrated) as a mask, and the passivation film 12SNB, the liner insulation film 12L and the barrier metal film 12BM (not illustrated) covering the end 12e of the Cu via-plug 12B are removed. With this, Cu filling the through via-plug 12B is exposed. Thereafter, the remaining resist film (not illustrated) is removed, and a barrier metal film 12BM_{N} of a refractory metal such as Ta or Ti and a Cu seed layer 12CSt are formed consecutively on the exposed surface of the projecting end 12e of the Cu via-plug 120B. Further, a resist pattern R₃ having resist openings R_{3A} and R_{3B} is formed on the Cu seed layer 12CSt in the step of FIG. 7L wherein it will be noted that each of the resist openings R_{3A} and R_{3B} exposes an area that includes two through via-plugs 12B.

Further, in the step of FIG. 7M, an electrolytic plating process of Cu is conducted while using the resist pattern R₃ as a mask, and with this, there are formed Cu connection pads (13a)₁ explained previously with reference to FIG. 2 in the resist openings R_{3A} and R_{3B}.

Further, the resist pattern R₃ is removed in the step of FIG. 7N, and the Cu seed layer 12CSt and the barrier metal film 12BMN remaining on the passivation film 12SNB are removed by a sputter etching process, or the like. Further, by dissolving the temporary adhesive film 101 in the step of FIG. 7O, the silicon wafer 120 is detached from the support substrate 100. Further the silicon wafer 120 is subjected to a dicing process, and the semiconductor chips 12 are obtained from the silicon wafer 120.

Further, a similar semiconductor chip 13 is placed upon the semiconductor chip 12 thus obtained by dicing as represented in FIG. 7P, such that the Cu connection pad (13a)₂ of the semiconductor chip 13 aligns with the Cu connection pad (13a)₁ of the semiconductor chip 12. Further a diffusion bonding process is applied such that the Cu connection pad (13a)₁ and the Cu connection pad (13a)₂ are merged or joined at a location represented by a broken line J. With this, the Cu connection pad 13a is formed. The diffusion bonding of the Cu connection pads may be conducted, after activating the surfaces of the Cu connection pads (13a)₁ and (13a)₂ by an Ar sputtering process, by way of a thermo compression bonding process in an nitrogen ambient at a temperature of 250° C. or higher for 10 minutes or more while exerting a pressure of 0.5-10 MPa from above.

Simultaneously, the Cu connection pad (14a)₁ on the top surface of the semiconductor chip causes a diffusion bonding with a corresponding Cu connection pad at a bottom surface of the semiconductor chip 14 not illustrated, and with this, the Cu connection pad 14a is formed. Further, the Cu connection pad 12a at the bottom surface of the semiconductor chip 12 causes a diffusion bonding with the Cu wiring pad 11a corresponding thereto on the package substrate 11.

Further, the sealing resins 12R, 13R and 14R are introduced consecutively into the gap between the package substrate 11 and the semiconductor chip 12, the gap between the semiconductor chip 12 and the semiconductor chip 13 and further the gap between the semiconductor chip 13 and the semiconductor chip 14, and with this, the three-dimensional semiconductor integrated circuit device 10 of FIGS. 1 and 2 is obtained.

According to the present embodiment, no solder bump is used for joining the wiring pad 11a and the through via-plug 12B, the through via-plugs 12B and 13B, or the through via-plug 13B and the connection pad 14b, and thus, it becomes possible to avoid the various problems associated with the use of the solder jointing such as diffusion of Sn in the through via-plugs and resulting formation of brittle intermetallic compounds, and the yield and reliability of the three-dimensional semiconductor integrated circuit device is improved significantly.

Further, according to the present embodiment, the wiring pads 11a, the through via-plugs 12B and 13B and the connection pads 14b are all formed of Cu of low specific resistance without using a solder, and thus, the operational characteristics of the semiconductor integrated circuit device are improved significantly as a result of suppression of signal delay caused by the RC product.

Further, with the present embodiment, the electric connection between the through via-plug 12B and the through via-plug 13B is attained via a connection pad formed to have a large area to cover the area including a plurality of through via-plugs, and thus, a stable joining is attained and occurrence of contact failure can be reduced.

Further, according to the present embodiment, as a result of use of the Cu connection pads, which can reduce the thickness to be smaller than the diameter of the via-plugs in place of the solder bumps, for the connection of the through via-plugs 12B and 13B, and thus, the overall height of the three-dimensional semiconductor integrated circuit 10 can be reduced. With this, it becomes possible to shorten the signal path length in the three dimensional direction inside the semiconductor integrated circuit device, and it becomes possible to suppress the parasitic impedance and increase the operational speed of the semiconductor device.

Further, with the present embodiment, a redundancy is secured as a result of the use of a plurality of through via-plugs for constructing a single signal path or current path as noted previously. Thus, it becomes possible to avoid that the semiconductor integrated circuit device 10 is rendered defective even in such a case there is caused a defect in one of the through via-plugs.

Further, with the present embodiment, in which through via-plugs of small diameter are disposed in the semiconductor chips that constitute a three-dimensional semiconductor integrated circuit device with high density, it becomes possible to increase the degree of freedom of constructing the current paths or signal paths in the three-dimensional semiconductor integrated circuit device, by bundling a plurality of threading via-holes by using a connection pad.

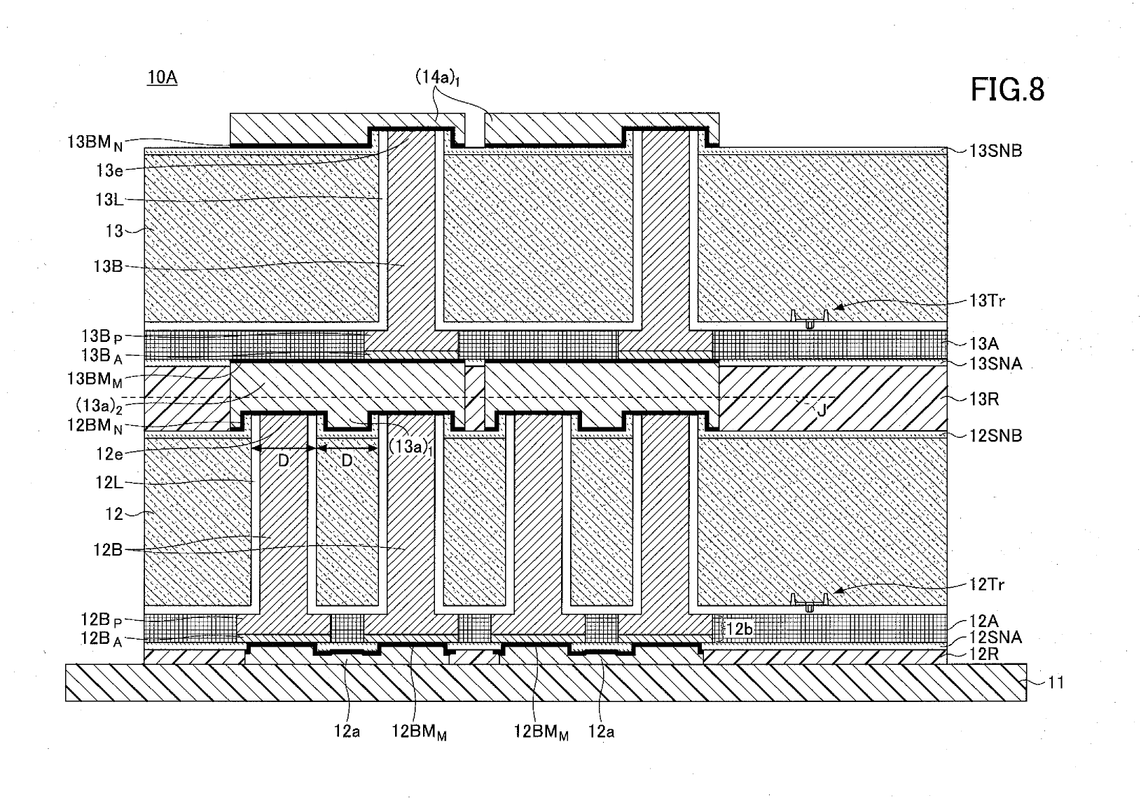

FIG. 8 is a cross-sectional diagram similar to that of FIG. 2 representing a part of a three-dimensional semiconductor integrated circuit device 10A according to a modification. In the drawings, those parts explained before are designated by the same reference numerals and the description thereof will be omitted.

Referring to FIG. 8, it will be noted that the density of the through via-plugs 13B in the semiconductor chip 13 is reduced to one half of the semiconductor chip 12.

In this embodiment, too, a desired redundancy is secured in the semiconductor chip 12. Further, because no solder is used for the connection of the semiconductor chip 12 and the semiconductor chip 13, the wiring length in the three-dimensional semiconductor integrated circuit device 10A is shortened. With this, the wiring resistance is also reduced.

Thus, it should be noted that the present embodiment should not be limited to the case in which the through-via plugs 12B in the semiconductor chip 12 and the through-via plugs 13B in the semiconductor chip 13 correspond one to one and that these through via-plugs are formed with the identical pitch.

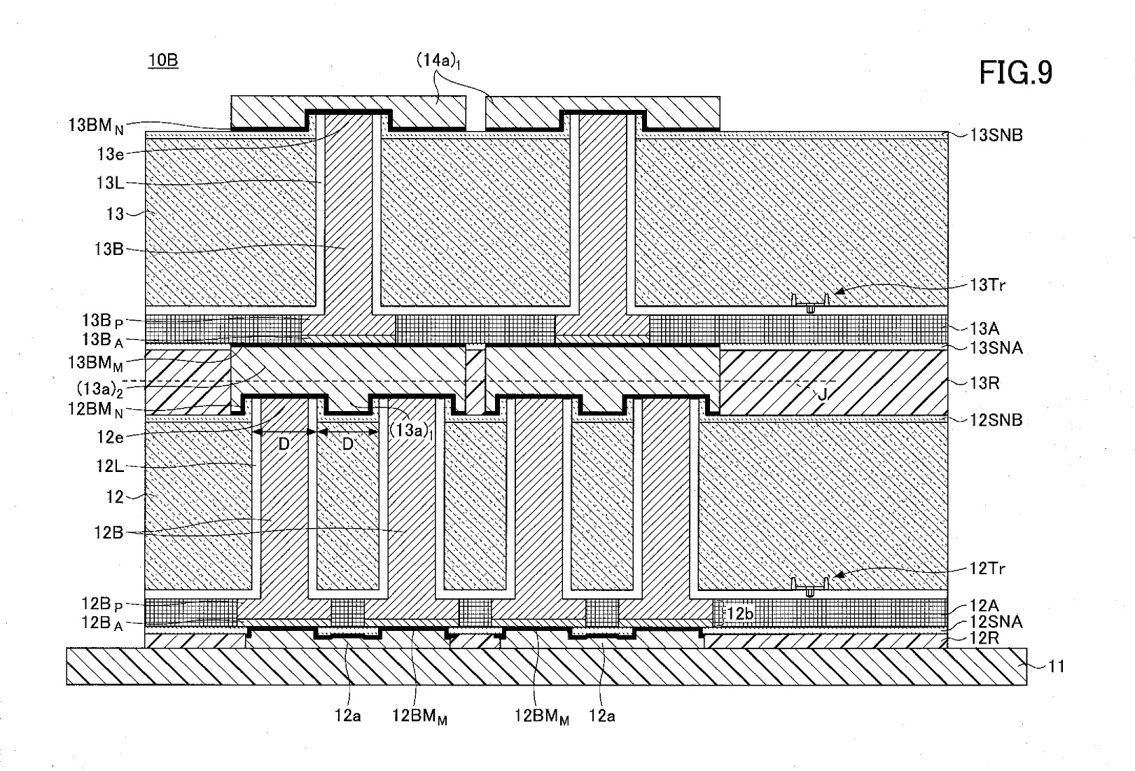

FIG. 9 is a cross-sectional diagram similar to that of FIG. 2 representing a part of a three-dimensional semiconductor integrated circuit device 10B which is a further modification of the construction of FIG. 8. In the drawings, those parts explained before are designated by the same reference numerals and the description thereof will be omitted.

With the present embodiment, it will be noted that the location of the through via-plugs 13B in the semiconductor chip 13 is shifted with regard to the location of the through via-plugs 12B in the semiconductor chip 12. Even in such a construction, a desired redundancy is secured for the semiconductor chip 12 similarly to the case of FIG. 8. Further, because no solder bump is used for the connection of the semiconductor chip 12 and the semiconductor chip 13, the wiring length in the three-dimensional semiconductor integrated circuit device 10B is shortened and the wiring resistance is reduced.

Further, with the present embodiment, in which the pitch of the through via-plugs 13B is set twice as large as the pitch of the through via-plug 12B, the procedure of relative alignment between the semiconductor chip 12 and the semiconductor chip 13 is substantially facilitated.

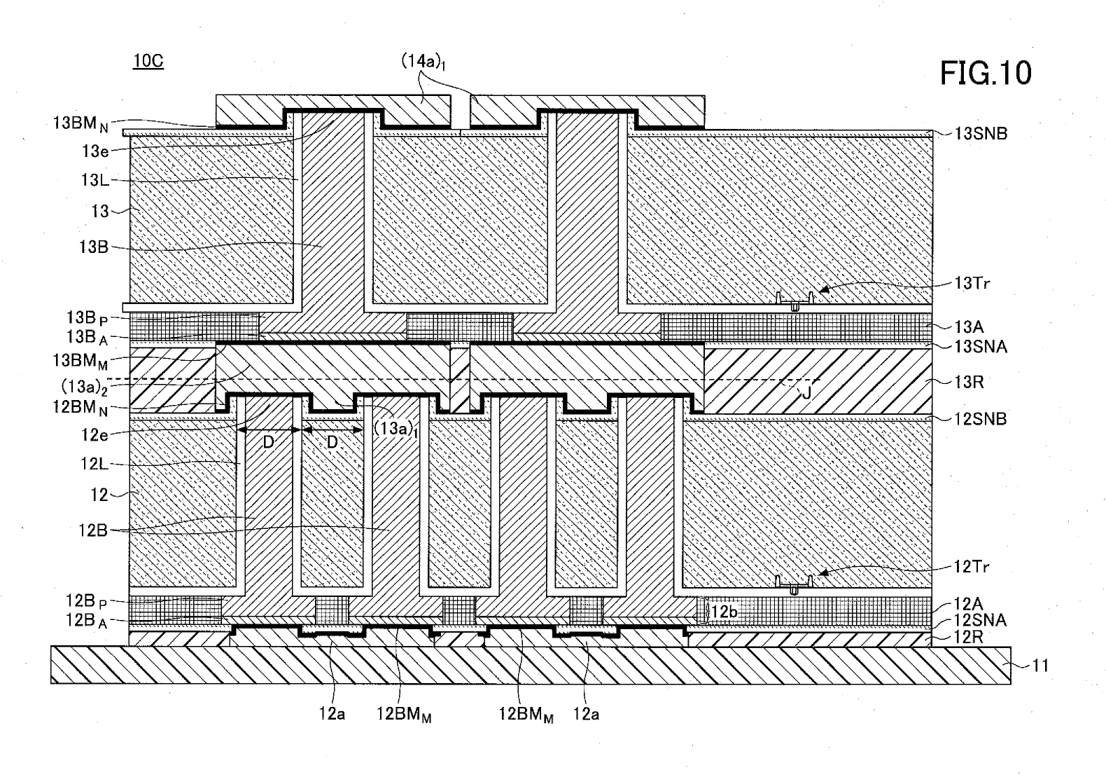

Further, FIG. 10 is a cross-sectional diagram similar to that of FIG. 2 representing a part of a three-dimensional semiconductor integrated circuit device 10C which is a further modification of the construction of FIG. 9. In the drawings, those parts explained before are designated by the same reference numerals and the description thereof will be omitted.

In the present embodiment, the diameter of the through via-plugs 13B is increased as compared with the through via-plugs 12B. Thus, with the present embodiment, it is possible to change the diameter of the through via-plugs for each semiconductor chip as necessary.

Further, it is obvious that the order of the semiconductor chips 12 and 13 may be reversed in each of the modifications of FIGS. 8-10.

While explanation has been made in the embodiments heretofore for the case in which the through via-plugs 12B and 13B and further the connection pads 12a and 13a are all formed of Cu. However, the present embodiment should not be limited to such a specific material but it is also possible to use a different low resistance metal such as Au in place of Cu.

While the present invention has been explained for preferred embodiments, the present invention is not limited to such specific embodiments and various variations and modifications may be made within the scope of the invention described in patent claims.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A semiconductor device comprising:
a first semiconductor chip having a first surface and a second surface opposite to said first surface, said first semiconductor chip including a first semiconductor element and a plurality of first through via-plugs each extending from said first surface to said second surface; and
a second semiconductor chip having a third surface and a fourth surface opposite to said third surface, said third semiconductor chip including a second semiconductor element and a plurality of second through via-plugs each extending from said third surface to said fourth surface,
said first semiconductor chip including a first connection pad on said first surface and a second connection pad on said second surface,
two of said first through via-plugs neighboring with each other being connected commonly to said first connection pad at said first surface and said two first through via-plugs being connected commonly to said first connection pad at said second surface in said first semiconductor chip,
said second semiconductor chip including a third connection pad on said third surface and a fourth connection pad on said fourth surface,
one of said second through via-plugs being connected to said third connection pad at said third surface and said one second through via-plug being connected to said fourth connection pad at said fourth surface in said second semiconductor chip,
said second semiconductor chip being stacked upon said first semiconductor chip such that said third surface faces said second surface,
said second connection pad and said third connection pad being joined with each other.

2. The semiconductor device as claimed in claim 1, wherein said second connection pad and said third connection pad have an identical size and an identical shape.

3. The semiconductor device as claimed in claim 1, wherein said first connection pad includes a connection pad of a first orientation connecting a pair of said first through via-plugs neighboring with each other in said first semiconductor chip and aligned in said first surface in a first direction and a connection pad of a second orientation connecting a pair of said first through via-plugs neighboring with each other in said first semiconductor chip and aligned in said first surface in a second direction crossing said first direction.

4. The semiconductor device as claimed in claim 1, wherein said first and second connection pads are connected with a plurality of said first through via-plugs neighboring with each other when viewed from a direction perpendicular to said first surface.

5. The semiconductor device as claimed in claim 1, wherein said second through via-plugs in said second semiconductor chip are formed in one to one correspondence with said first through via-plugs in said first semiconductor chip with an identical diameter and an identical pitch, two of said second through via-plugs are connected commonly to said third connection pad on said third surface in said second semiconductor chip and two of said second through via-plugs are connected commonly to said fourth connection pad on said fourth surface in said second semiconductor chip.

6. The semiconductor device as claimed in claim 5, wherein said first through via-plugs and said second through via-plugs are formed in said first and second semiconductor chips with a pitch twice as large as a diameter of said first through via-plugs and said second through via-plugs.

7. The semiconductor device as claimed in claim 1, wherein said second through via-plugs are formed in said second semiconductor chip with a pitch different from a pitch of said first through via-plugs in said first semiconductor chip.

8. The semiconductor device as claimed in claim 7, wherein said second through via-plugs are formed in said second semiconductor chip with a diameter different from a diameter of said first through via-plugs in said first semiconductor chip.

9. The semiconductor device as claimed in any of claim 1, wherein said first through fourth connection pads are formed of an identical metal.

10. The semiconductor device as claimed in claim 9, wherein said first through fourth connection pads are formed of Cu or Au.

11. The semiconductor device as claimed in claim 1, further comprising a package substrate, wherein said first semiconductor chip is mounted upon said package substrate such that said first surface faces said package substrate, and wherein said first connection pad is joined directly to a connection pad on said package substrate.

12. A method of manufacturing a semiconductor device comprising:
placing a second semiconductor chip upon a first semiconductor chip, said first semiconductor chip having a first surface and a second surface opposite to said first surface, said first semiconductor chip having a first semiconductor element and formed with a plurality of first through via-plugs extending from said first surface to said second surface, said first semiconductor chip having a first connection pad on said first surface connecting at least two neighboring first through via-plugs and a second connection pad on said second surface connecting said at least two first neighboring through via-plugs, said second semiconductor chip having a third surface and a fourth surface opposite to said third surface, said second semiconductor chip having a second semiconductor element and formed with a plurality of second through via-plugs extending from said third surface to said fourth surface, said second semiconductor chip having a third connection pad on said third surface to connect at least two neighboring second through via-plugs and a second connection pad on said fourth surface to connect said at least two neighboring second through via-plugs, said step of placing said second semiconductor chip upon said first semiconductor chip being conducted such that said third connection pad makes a contact upon said second connection pad; and
diffusion bonding said second connection pad and said third connection pad with each other.

13. The method as claimed in claim 12, further comprising a step of diffusion bonding said first connection pad upon a wiring pad on a package substrate.
